(19) United States
(12) Patent Application Publication
(10) Pub. No.: US 2024/0250504 A1
(43) Pub. Date: Jul. 25, 2024

(54) METHOD OF MANUFACTURING SEMICONDUCTOR OPTICAL ELEMENT

(71) Applicant: Sumitomo Electric Industries, Ltd., Osaka (JP)

(72) Inventor: Takehiko KIKUCHI, Osaka-shi (JP)

(73) Assignee: Sumitomo Electric Industries, Ltd., Osaka (JP)

(21) Appl. No.: 18/402,936

(22) Filed: Jan. 3, 2024

(30) Foreign Application Priority Data
Jan. 23, 2023 (JP) 2023-008059

(51) Int. Cl. H01S 5/20; H01S 5/02; H01S 5/30; H01S 5/323

(52) U.S. Cl. CPC H01S 5/2086; H01S 5/0203; H01S 5/0217; H01S 5/0218; H01S 5/3013; H01S 5/3235

(57) ABSTRACT

A method of manufacturing a semiconductor optical element including a chip including a III-V compound semiconductor and a first substrate. The chip includes a second substrate and a semiconductor layer stacked on the second substrate. The method includes, bonding the semiconductor layer of the chip to the first substrate, forming a mask on the chip bonded to the first substrate, and removing the second substrate by performing etching on the chip provided with the mask. The mask has an opening. The second substrate is exposed from the opening. The opening does not have a side perpendicular to a first direction. The etching in the removing the second substrate is more likely to progress in a second direction intersecting with the first direction than in the first direction.

### CROSS REFERENCE TO RELATED APPLICATIONS

This application claims priority based on Japanese Patent Application No. 2023-008059 filed on Jan. 23, 2023, and the entire contents of the Japanese patent application are incorporated herein by reference.

### TECHNICAL FIELD

The present disclosure relates to a method of making a semiconductor optical element.

### BACKGROUND

There is known a technique for bonding a semiconductor element formed of a compound semiconductor and including an optical gain to a substrate such as an SOI (Silicon On Insulator) substrate (silicon photonics) on which a waveguide is formed (for example, PTL 1). For example, a semiconductor layer is grown on a wafer of a compound semiconductor such as indium phosphide (InP). Semiconductor elements are formed by cutting the wafer. The semiconductor element is bonded to the SOI substrate. After bonding, etching or the like is performed on the semiconductor element.

PTL 1: Japanese Unexamined Patent Application Publication No. 2015-164148

### SUMMARY

### Means for Solving the Problem

According to one aspect of the present disclosure, there is provided a method of manufacturing a semiconductor optical element including a chip including a III-V compound semiconductor and a first substrate. The chip includes a second substrate and a semiconductor layer stacked on the second substrate. The method includes, bonding the semiconductor layer of the chip to the first substrate, forming a mask on the chip bonded to the first substrate, and removing the second substrate by performing etching on the chip provided with the mask. The mask has an opening. The second substrate is exposed from the opening. The opening does not have a side perpendicular to a first direction. The etching in the removing the second substrate is more likely to progress in a second direction intersecting with the first direction than in the first direction.

### BRIEF DESCRIPTION OF THE DRAWINGS

FIG. 1A is a perspective view showing a semiconductor optical element according to a first embodiment.

FIG. 1B is a cross-sectional view taken along line A-A of FIG. 1A.

FIG. 2A shows a method of manufacturing a semiconductor optical element.

FIG. 2B shows a method of manufacturing a semiconductor optical element.

FIG. 3A shows a method of manufacturing a semiconductor optical element.

FIG. 3B shows a method of manufacturing a semiconductor optical element.

FIG. 4A shows a method of manufacturing a semiconductor optical element.

FIG. 4B shows a method of manufacturing a semiconductor optical element.

FIG. 5A shows a method of manufacturing a semiconductor optical element.

FIG. 5B shows a method of manufacturing a semiconductor optical element.

FIG. 6A shows a method of manufacturing a semiconductor optical element.

FIG. 6B shows a method of manufacturing a semiconductor optical element.

FIG. 7A shows a method of manufacturing a semiconductor optical element.

FIG. 7B shows a method of manufacturing a semiconductor optical element.

FIG. 8A shows a method of manufacturing a semiconductor optical element.

FIG. 8B shows a method of manufacturing a semiconductor optical element.

FIG. 9A shows a method of manufacturing a semiconductor optical element.

FIG. 9B shows a method of manufacturing a semiconductor optical element.

FIG. 10A shows a method of manufacturing a semiconductor optical element.

FIG. 10B shows a method of manufacturing a semiconductor optical element.

FIG. 11A shows a method of manufacturing a semiconductor optical element.

FIG. 11B shows a method of manufacturing a semiconductor optical element.

FIG. 12A is a plan view showing a method of manufacturing a semiconductor optical element according to a comparative example.

FIG. 12B is a cross-sectional view taken along line D-D of FIG. 12A.

FIG. 13A is a plan view showing a method of manufacturing a semiconductor optical element according to a comparative example.

FIG. 13B is a cross-sectional view taken along line D-D of FIG. 13A.

FIG. 14A is a plan view showing a method of manufacturing a semiconductor optical element according to a second embodiment.

FIG. 14B is a cross-sectional view taken along line D-D of FIG. 14A.

FIG. 15A is a plan view showing a method of manufacturing a semiconductor optical element according to a first modification.

FIG. 15B is an enlarged view of the opening.

FIG. 16A is a plan view showing a method of manufacturing a semiconductor optical element according to a second modification.

FIG. 16B is an enlarged view of the opening.

FIG. 17A is a plan view showing a method of manufacturing a semiconductor optical element according to a third modification.

FIG. 17B is an enlarged view of the opening.

### DETAILED DESCRIPTION

In etching after bonding, residues may be generated due to anisotropy of etching. The residue can be an obstacle to a subsequent process for example, such as application of a resist. It is therefore an object to provide a method of manufacturing a semiconductor optical element capable of reducing the occurrence of residues in etching.

### Description of Embodiments of Present Disclosure

First, the contents of embodiments of the present disclosure will be listed and explained.

According to one aspect of the present disclosure, there is provided a method of manufacturing a semiconductor optical element including a chip including a III-V compound semiconductor and a first substrate. The chip includes a second substrate and a semiconductor layer stacked on the second substrate. The method includes, bonding the semiconductor layer of the chip to the first substrate, forming a mask on the chip bonded to the first substrate, and removing the second substrate by performing etching on the chip provided with the mask. The mask has an opening. The second substrate is exposed from the opening. The opening does not have a side perpendicular to a first direction. The etching in the removing the second substrate is more likely to progress in a second direction intersecting with the first direction than in the first direction. Since the opening does not have a side perpendicular to the first direction, a surface having a low etching rate is hardly exposed in the etching of the second substrate. Etching of the second substrate is likely to proceed. The occurrence of residues in etching can be reduced.

(2) In the above (1), the opening may have a planar shape of a circle. Since the opening does not have a side perpendicular to the first direction, a surface having a low etching rate is hardly exposed in the etching of the second substrate. Etching of the second substrate is likely to proceed. Generation of residue in etching is reduced.
(3) In the above (1) or (2), the opening of the mask may be one opening. Since the opening does not have a side perpendicular to the first direction, a surface having a low etching rate is hardly exposed in the etching of the second substrate. Etching of the second substrate is likely to proceed. Generation of residue in etching is reduced.
(4) In any one of (1) to (3), a distance from an end portion of the opening to an end portion of the second substrate in the first direction may be ¼ to two times a thickness of the second substrate. Etching proceeds in the thickness direction of the second substrate and also in directions parallel to the plane of the second substrate. The etching proceeds to the semiconductor layer and reaches the end portion of the second substrate. The occurrence of residue can be reduced.
(5) In the above (1) or (2), the opening of the mask may include a plurality of openings. Since the opening does not have a side perpendicular to the first direction, a surface having a low etching rate is hardly exposed in the etching of the second substrate. Etching of the second substrate is likely to proceed. The occurrence of residues in etching can be reduced.
(6) In the above (5), a distance between two of the openings adjacent to each other in the first direction may be two times or less as large as a thickness of the second substrate. Etching proceeds in the thickness direction of the second substrate and also in directions parallel to the plane of the second substrate. Portions of the second substrate between the openings are removed by etching. The occurrence of residue can be reduced.
(7) In the above (5) or (6), the opening may have a long axis and a short axis. The long axis may be inclined with respect to the second direction. A surface having a low etching rate is hardly exposed in the etching of the second substrate. Etching of the second substrate is likely to proceed. The occurrence of residue in etching is reduced.
(8) In the above (7), the long axis may have an inclination angle of 300 to 150° from the second direction. A surface having a low etching rate is hardly exposed in the etching of the second substrate. Etching of the second substrate is likely to proceed. The occurrence of residue in etching is suppressed.
(9) In the above (7) or (8), the opening may have a planar shape of any one of an ellipse, a rectangle, and a rhombus. A surface having a low etching rate is hardly exposed in the etching of the second substrate. Etching of the second substrate is likely to proceed. The occurrence of residue in etching is suppressed.
(10) In any one of (1) to (9), the second substrate may include indium phosphide. The semiconductor layer may include indium gallium arsenide. In the removing the second substrate, the second substrate may be removed by wet etching using an etchant including hydrochloric acid. A high etch selectivity is obtained between the second substrate and the semiconductor layer. The second substrate is removed by etching. The etching stops at the semiconductor layer.
(11) In any one of (1) to (10), the semiconductor layer may include a first semiconductor layer and a second semiconductor layer. The second substrate, the first semiconductor layer, and the second semiconductor layer may be stacked in this order. In the bonding, the second semiconductor layer may be bonded to the first substrate. The method may include, removing the first semiconductor layer after the removing the second substrate, and etching the second semiconductor layer. The influence of residue on the processing of the second semiconductor layer is reduced.

### DETAILS OF EMBODIMENTS OF PRESENT DISCLOSURE

Specific examples of a method of manufacturing a semiconductor optical element according to embodiments of the present disclosure will be described below with reference to the drawings. It is noted that, the present disclosure is not limited to these examples, and is defined by the scope of the claims, and is intended to include all modifications within the meaning and scope equivalent to the scope of the claims.

### First Embodiment

### (Semiconductor Optical Element)

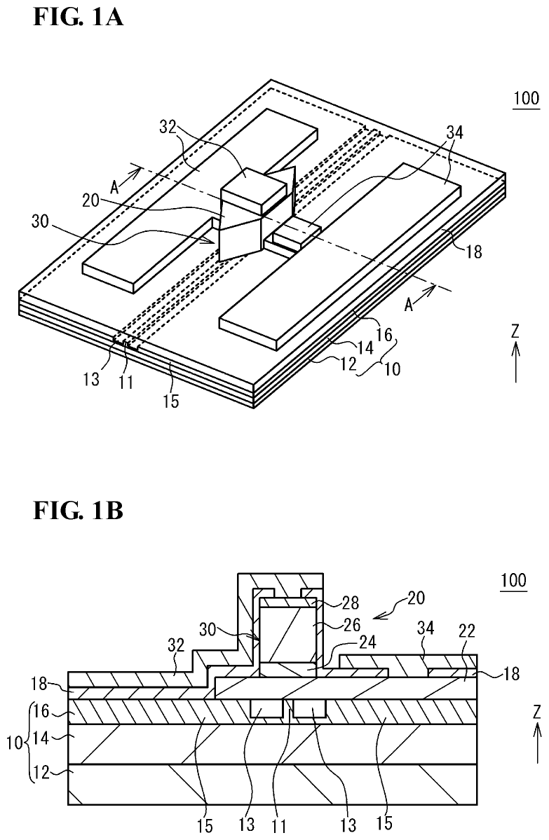

FIG. 1A is a perspective view showing a semiconductor optical element 100 according to a first embodiment. FIG. 1B is a cross-sectional view taken along line A-A of FIG. 1A. As shown in FIGS. 1A and 1i, semiconductor optical element 100 is a hybrid laser device including a substrate 10 (first substrate) and a semiconductor element 20. Semiconductor element 20 is an element including a group III-V compound semiconductor layer. Semiconductor element 20 has, for example, an optical gain and generates light. In another example, semiconductor element 20 is photo-sensitive and absorbs light to generate a photocurrent. Semiconductor element 20 may modulate light by changing a refractive index according to a voltage. Light propagates through substrate 10. The Z-axis direction is a normal direction of the upper surface of substrate 10.

As shown in FIG. 1B, substrate 10 is an SOI substrate including a substrate 12, a box layer 14, and a silicon (Si) layer 16 sequentially stacked in the Z-axis direction. Substrate 12 is formed of, for example, Si. Box layer 14 is formed of, for example, silicon oxide (SiO₂). The thickness of box layer 14 is, for example, 3 μm. The thickness of Si layer 16 is, for example, 220 nm. The upper surface of substrate 10 is covered with an insulating film 18. Insulating film 18 is formed of, for example, a 1 μm-thick SiO₂. The refractive index of Si layer 16 is 3.45. The refractive index of box layer 14 and insulating film 18 is 1.45, which is lower than that of Si layer 16.

Si layer 16 of substrate 10 includes a waveguide 11, two recesses 13, and two terraces 15. Waveguide 11 and recess 13 extend in the same direction. Two recesses 13 are located on both sides of waveguide 11 and extend in the same direction as waveguide 11. Terrace 15 is a plane of Si layer 16, recess 13 is located between terrace 15 waveguide 11. Although the bottom surface of recess 13 is Si layer 16 in FIG. 1B, the bottom surface may be box layer 14. Si layer 16 may be provided with optical components such as a ring resonator and a loop mirror. For example, a ring resonator is formed by bending waveguide 11 in a ring shape.

As shown in FIG. 1B, semiconductor element 20 is bonded to the upper surface of Si layer 16, that is, is located over waveguide 11 and recess 13. Semiconductor element 20 includes a cladding layer 22, an active layer 24, a cladding layer 26 and a contact layer 28. Cladding layer 22 to contact layer 28 are sequentially stacked upward from the upper surface of substrate 10.

Cladding layer 22 is formed of, for example, 400 nm thick n-type indium phosphide (n-InP). Cladding layer 26 is formed of, for example, p-InP having a thickness of 2 μm. Contact layer 28 is formed of (p+)-gallium indium arsenide (GaInAs) or the like. Active layer 24 includes a plurality of alternately stacked well layers and barrier layers, and has a multi-quantum well (MQW) structure. The well layer and the barrier layer are formed of non-doped gallium indium arsenide phosphide (i-GaInAsP) or the like. Active layer 24 is, for example, 300 nm thick. Active layer 24 has an optical gain and emits light having a wavelength of 1.55 μm, for example. Each layer of semiconductor element 20 may be formed of a group III-V compound semiconductor other than those described above.

As shown in FIG. 1A, semiconductor element 20 includes a mesa 30 and electrodes 32 and 34. Mesa 30 of semiconductor element 20 is located on waveguide 11. The tip of mesa 30 has a tapered shape and is tapered along waveguide 11. Mesa 30 of semiconductor element 20 and tapered tip or the like, is the element structure.

As shown in FIG. 1B, mesa 30 is formed of active layer 24, cladding layer 26, and contact layer 28 and is located over waveguide 11. Cladding layer 22 is located between mesa 30 and substrate 10 and extends outside mesa 30. Cladding layer 22 is in contact with the upper surface of waveguide 11 and the upper surface of terrace 15 of substrate 10. The surfaces of mesa 30 and cladding layer 22 are covered with insulating film 18. Insulating film 18 includes an opening over mesa 30 and over cladding layer 22.

As shown in FIG. 1B, electrode 32 extends from the top of mesa 30 to the top surface of insulating film 18 outside mesa 30. Electrode 32 is electrically connected to contact layer 28 through the opening of insulating film 18. Electrode 32 is formed of, for example, a laminate of titanium (Ti), platinum (Pt), and gold (Au). Electrode 34 is spaced apart from electrode 32 and is provided on the upper surface of insulating film 18 and is electrically connected to cladding layer 22 through an opening in insulating film 18. Electrode 34 is formed of, for example, a metal such as an alloy of gold, germanium, and nickel (AuGeNi). A plating layer of Au or the like may be provided with electrode 32 and electrode 34.

A voltage is applied to electrodes 32 and 34 to inject carriers into active layer 24 of semiconductor element 20. By injecting carriers, active layer 24 generates light. Semiconductor element 20 and substrate 10 are optically coupled by evanescent optical coupling, and the light transits to waveguide 11 of substrate 10. The light propagates through waveguide 11 and is emitted from the end portion of substrate 10 to the outside of semiconductor optical element 100.

### (Production Method)

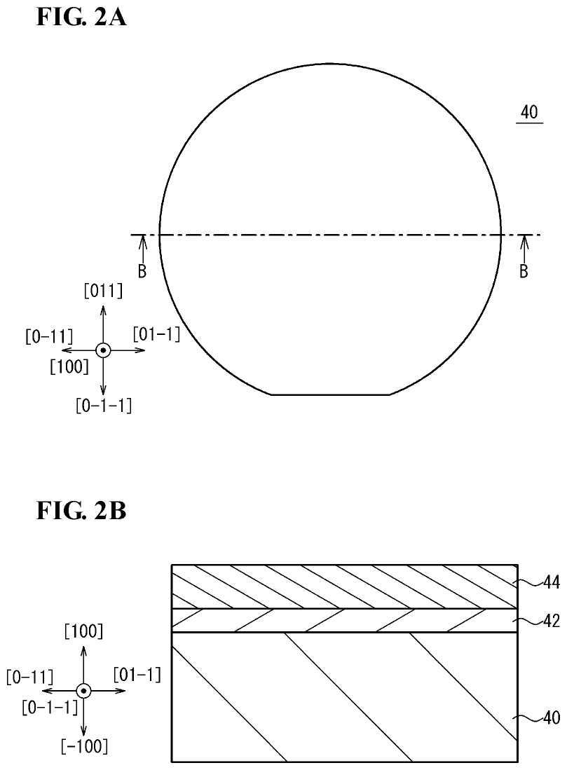

FIGS. 2A to 11B shows a method of fabricating semiconductor optical element 100. FIG. 2A is a plan view showing a substrate 40 (second substrate). FIG. 2B is a cross-sectional view taken along line B-B of FIG. 2A. The direction of the crystal of substrate 40 is shown in the drawing. In FIG. 2A, the surface of substrate 40 is the (100) plane. The direction from back to front is the [100] direction. The upper is the [011] direction. The lower is the [0−1−1] direction. The right is the [01−1] direction. The left is the [0−11] direction. The [0−11] direction and the [01−1] direction correspond to the first direction. The [011] direction and the [0−1−1] direction correspond to the second direction, and intersect the [0−11] direction and the [01−1] direction. The [011] direction and the [0−1−1] direction are orthogonal to the [0−11] direction and the [01−1] direction.

Substrate 40 shown in FIG. 2A is, for example, a 2-inch InP substrate. As shown in FIG. 2B, an etching stop layer 42 (first semiconductor layer) and a semiconductor layer 44 (second semiconductor layer) epitaxially grow in this order on one surface of substrate 40 by, for example, metalorganic vapor phase epitaxy (MOVPE). Semiconductor layer 44 includes cladding layer 22, active layer 24, cladding layer 26, and contact layer 28 shown in FIG. 1B. Over etching stop layer 42, cladding layer 22, active layer 24, cladding layer 26, and contact layer 28 are stacked in this order. Substrate 40 is formed of, for example, indium phosphide (InP) having a thickness of 350 m. Etching stop layer 42 is formed of, for example, indium gallium arsenide (InGaAs) having a thickness of 0.3 μm. After the growth of semiconductor layer 44, dicing is performed.

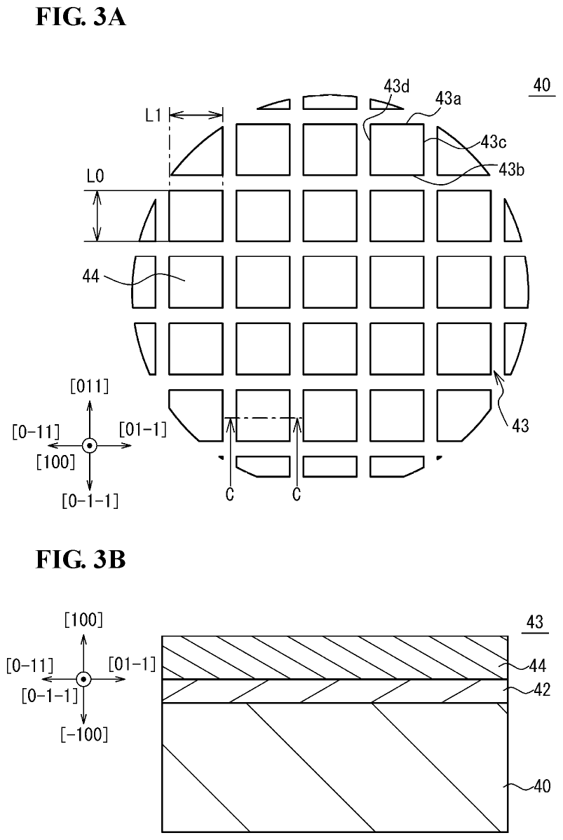

FIG. 3A is a plan view showing substrate 40 after dicing. FIG. 3B is a cross-sectional view taken along line C-C of FIG. 3A and shows a cross-section including one chip 43. InP is susceptible to cracking along the [0−11] and [0−1−1] directions. The wafer is divided along these directions. As shown in FIG. 3A, the wafer is divided by dicing to form a plurality of chips 43. Substrate 40 formed of an InP-based semiconductor is likely to break with the (01−1) plane and the (0−1−1) plane as cleavage planes. Semiconductor layer 44, etching stop layer 42, and substrate 40 are cut along the [011] direction and the [0−1−1] direction. Semiconductor layer 44, etching stop layer 42, and substrate 40 are cut along the [0−11] direction and the [01−1] direction. Chip 43 is formed by dicing. As shown in FIG. 3B, chip 43 includes substrate 40, etching stop layer 42 and semiconductor layer 44.

Chip 43 has a planar shape of a rectangle. Substrate 40 includes a side 43a, a side 43b, a side 43c and a side 43d. Side 43a and side 43b are opposite to each other and perpendicular to the [011] direction and the [0−1−1] direction. Side 43c and side 43d are opposite to each other and perpendicular to the [01−1] direction and the [0−11] direction. Length L1 of side 43a and side 43b of chip 43 is, for example, 3.2 mm. Length L0 of side 43c and side 43d of chip 43 is, for example, 3.2 mm. Length L1 may be equal to length L0 or may be different from length L0.

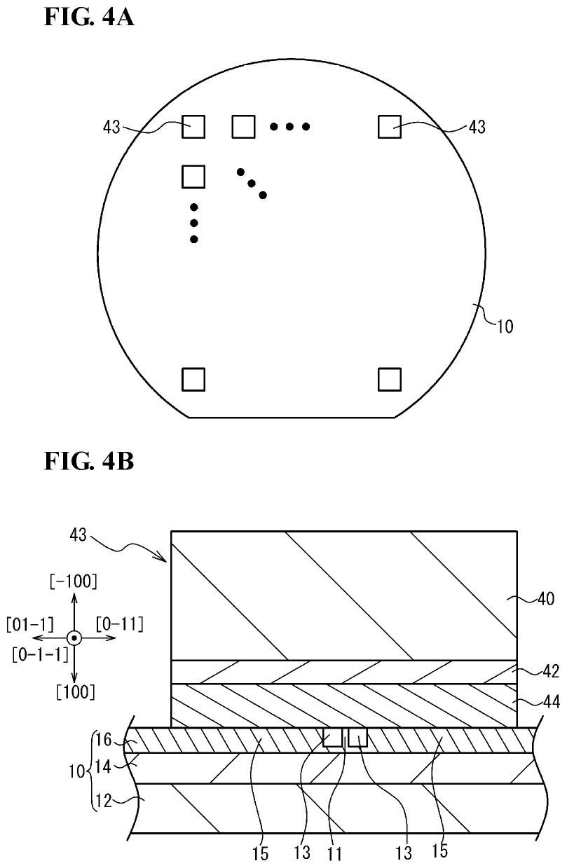

FIG. 4A is a plan view showing substrate 10. Substrate 10 is, for example, a wafer having a diameter of 10 inches. As shown in FIG. 4A, a plurality of chips 43 are bonded to substrate 10. The bonding method may be hydrophilic bonding, plasma activated bonding, or the like. The surface of semiconductor layer 44 of chip 43 and the surface of Si layer 16 of substrate 10 are hydrophilized or activated by plasma irradiation.

FIG. 4B is a cross-sectional view showing a drawing including one chip 43. As shown in FIG. 4B, the surface of semiconductor layer 44 is opposed to and in contact with the surface of Si layer 16 of substrate 10. After the contact, heat treatment is performed at a temperature of, for example, 300° C. to increase the bonding strength. In the Z-axis direction, substrate 10, semiconductor layer 44, etching stop layer 42, and substrate 40 are arranged in this order. Substrate 40 of chip 43 is located opposite to substrate 10 across semiconductor layer 44 and etching stop layer 42. As shown in FIG. 4B, semiconductor layer 44 is bonded onto waveguide 11 of substrate 10.

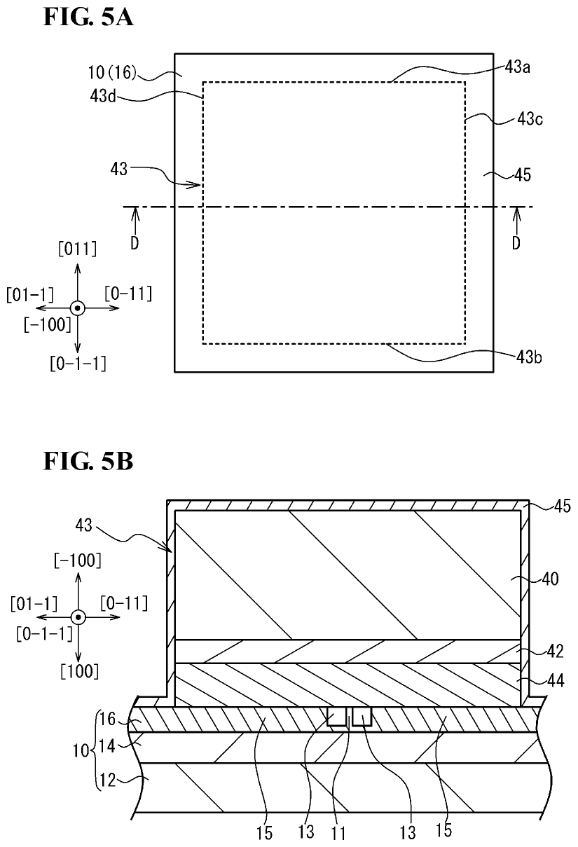

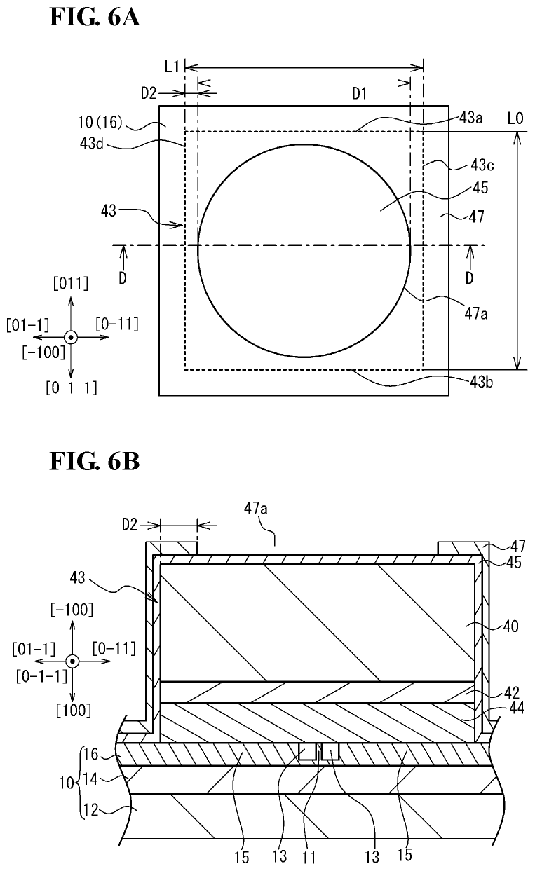

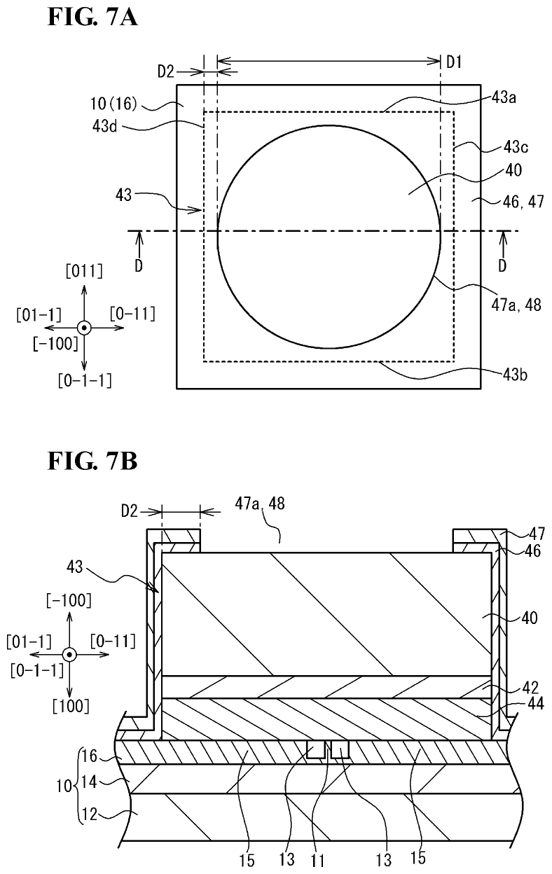

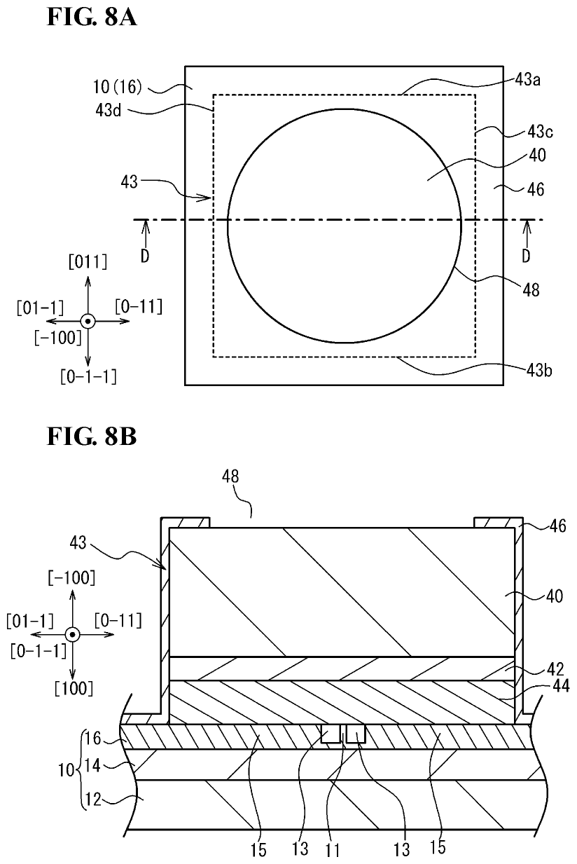

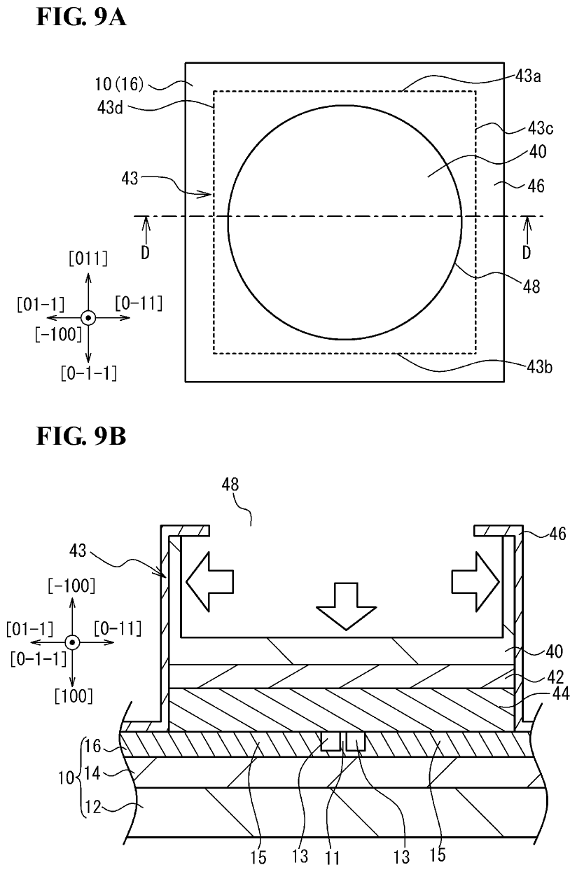

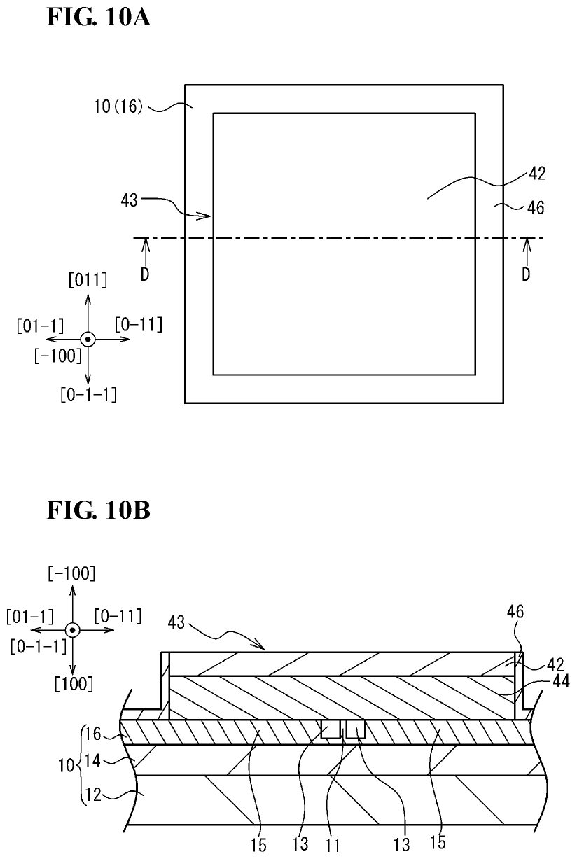

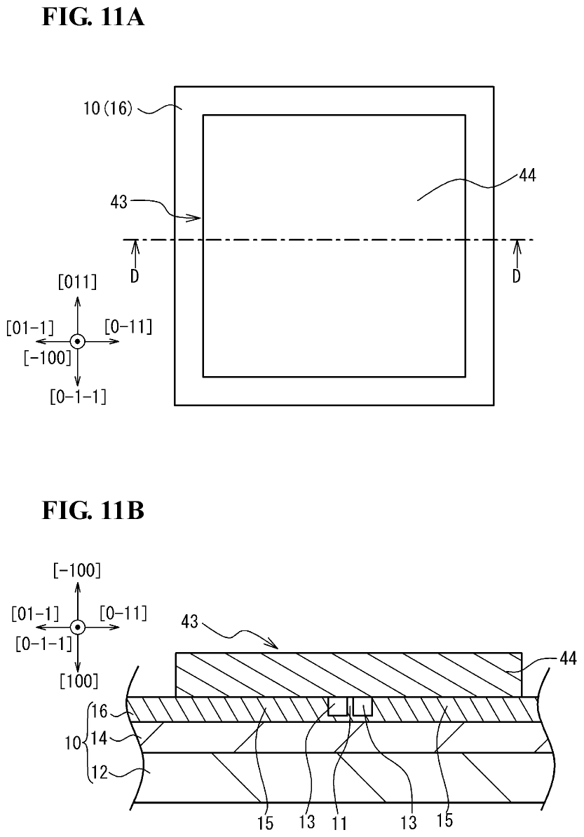

FIG. 5A, FIG. 6A, FIG. 7A, FIG. 8A, FIG. 9A, FIG. 10A and FIG. 11A are plan views showing planes including one chip. FIG. 5B, FIG. 6B, FIG. 7B, FIG. 8B, FIG. 9B, FIG. 10B and FIG. 11B are cross-sectional views along line D-D of the corresponding plan view.

As shown in FIGS. 5A and 5B, an insulating film 45 is formed by, for example, a plasma chemical vapor deposition (CVD) method. Insulating film 45 covers the top surface of substrate 10 and the side and top surfaces of chip 43. Insulating film 45 is formed of an insulating material such as silicon oxide (SiO₂). The thickness of insulating film 45 on the upper surface of chip 43 is, for example, 1 μm. The thickness of the side surface of chip 43 is, for example, 0.5 μm.

As shown in FIGS. 6A and 6B, a resist 47 is formed on the surface of insulating film 45. Resist 47 is patterned by photolithography and etching or the like to form an opening 47a in resist 47. Opening 47a is located on chip 43 and approximately at the center of the plane of chip 43. As shown in FIG. 6A, opening 47a has a planar shape of circle. The end portion of opening 47a is spaced apart from side 43a, side 43b, side 43c, and side 43d of chip 43, and is surrounded by the four sides.

Diameter D1 of opening 47a is smaller than side lengths L0 and L1 of chip 43. The shortest distance D2 between the end portion of opening 47a and the end portion of chip 43 in the [01−1] direction (the distance from the end portion of opening 47a to side 43d) is, for example, 100 μm to 500 μm. A distance from opening 47a to side 43a, a distance to side 43b, and a distance to side 43c are each approximately equal to D2 and may be equal to D2. Insulating film 45 is exposed from opening 47a.

As shown in FIGS. 7A and 7B, the pattern of resist 47 is transferred to insulating film 45 by etching using, for example, buffered hydrofluoric acid. A Mask 46 is formed from insulating film 45 by etching. Mask 46 includes an opening 48. Opening 48 overlaps opening 47a of resist 47 and passes through mask 46. Substrate 40 is exposed from opening 48. Opening 48 has a planar shape of circle. Opening 48 does not include a side perpendicular to the [01−1] direction and a side perpendicular to the [0−11] direction. The diameter of opening 48 is equal to diameter D1 of opening 47a. The distance from the end portion of opening 48 to the end portion of chip 43 is equal to the distance from the end portion of opening 47a to the end portion of chip 43 (for example, D2). Substrate 40 of chip 43 is exposed from opening 48. As shown in FIGS. 8A and 8B, resist 47 is removed. Mask 46 is exposed.

As shown in FIGS. 9A to 10B, wet etching is performed from the back surface of substrate 40. When substrate 40 is an InP substrate, the back surface of substrate 40 is a (−100) plane. When substrate 40 is an InP substrate, a solution containing hydrochloric acid (HCl) is used as the etchant. The etchant solution is selected according to the material constituting substrate 40.

As shown in FIG. 9A, opening 48 of mask 46 has a shape of circle. A circular area of substrate 40 is exposed through opening 48. The exposed face is the (−100) face. When wet etching is performed on the (−100) plane of the InP substrate using a hydrochloric acid-based etchant, the etching proceeds in the thickness direction of substrate 40, that is, in the [100] direction, as shown in FIG. 9B. The wet etching proceeds in the [100] direction and also in directions parallel to the plane of substrate 40. That is, the wet etching proceeds three dimensionally in all directions.

The wet etching of substrate 40 is anisotropic. Etching also proceeds in the [01−1] direction, the [0−11] direction, the [011] direction, and [0−1−1] direction. The ease of progress of etching varies depending on the direction. The etching rate in the direction perpendicular to the plane forming an angle of 35 degrees with the (−100) plane is extremely small, and the etching hardly proceeds in this direction. The time from the start of wet etching of substrate 40 until substrate 40 is dissolved away in a certain direction is defined as the etching rate in that direction. The etching rate in the [01−1] direction and the etching rate in the [0−11] direction are smaller than the etching rate in the [011] direction and the etching rate in the [0−1−1] direction.

As shown in FIG. 9A, opening 48 of mask 46 has a shape of circle. and does not include a side perpendicular to the [01−1] direction and the [0−11] direction. A surface having a small etching rate is hardly exposed. As shown in FIG. 9B, the wet etching proceeds in the [100] direction as well as in directions parallel to the plane and into the portion of substrate 40 under mask 46. The wet etching reaches etching stop layer 42 in the [100] direction and stops at etching stop layer 42. The wet etching reaches side 43a, side 43b, side 43c and side 43d of chip 43. As shown in FIGS. 10A and 10B, substrate 40 is removed from chip 43 by wet etching. Etching stop layer 42 is exposed. After completion of the wet etching, mask 46 is removed by etching using buffered hydrofluoric acid (BHF). After removing mask 46, a post-process is performed on chip 43.

As shown in FIGS. 11A and 111B, etching stop layer 42 is removed. Semiconductor layer 44 is exposed. A resist pattern, an etching mask and the like are provided on semiconductor layer 44. Etching is performed to form semiconductor element 20 shown in FIGS. 1A and 1B from semiconductor layer 44. Semiconductor optical element 100 is formed.

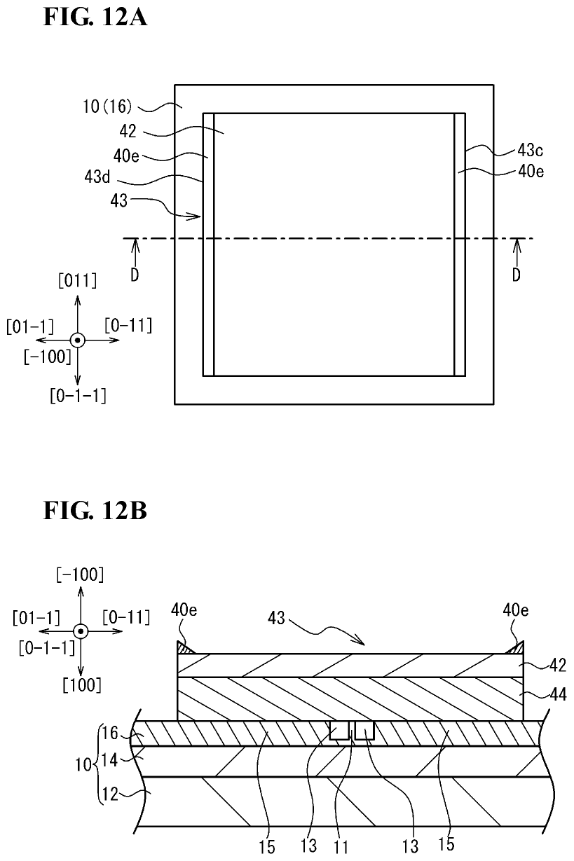

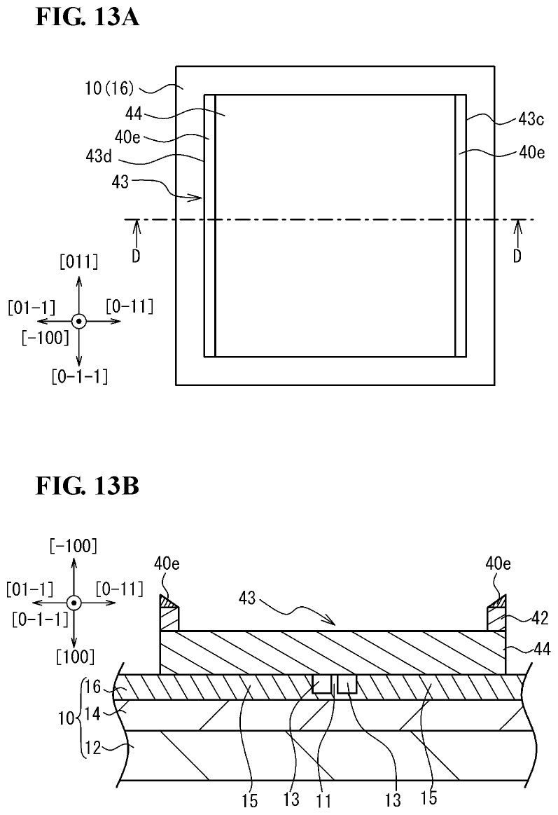

FIGS. 12A and 13A are plan views showing a method of fabricating a semiconductor optical element according to a comparative example. FIGS. 12B and 13B are cross-sectional views along line D-D of the corresponding plan view. After chip 43 is bonded to substrate 10, substrate 40 is wet etched without providing a mask.

In the wet etching of substrate 40, when the etching proceeds in the [01−1] direction and the [0−11] direction, a specific crystal plane having an angle of 35 degrees with respect to the (−100) plane and extending in parallel to the [011] direction is likely to be exposed. The etching rate in the direction perpendicular to the plane inclined at 35 degrees with respect to the (−100) plane is extremely small. When a surface inclined at an angle of 35 degrees is exposed, etching hardly proceeds in a direction perpendicular to the surface. Compared with the [011] direction and the [0−1−1] direction, etching is hardly proceed in the [01−1] direction and the [0−11] direction.

As shown in FIGS. 12A and 12B, a portion of substrate 40 is not removed in the [01−1] direction and the [0−11] direction and remains as residue 40e. After substrate 40 is wet-etched, etching stop layer 42 is wet-etched. As shown in FIGS. 13A and 13B, residue 40e and underlying etching stop layer 42 remain. Residue 40e extends along side 43c and side 43d. Residue 40e protrudes upward from the top surface of etching stop layer 42. Residue 40e has a triangular cross-sectional shape. The base angle of residue 40e is, for example, 35 degrees. The height of residue 40e is, for example, 20 μm. The length of the bottom side of residue 40e is, for example, 30 μm. Due to the presence of residue 40e, it is difficult to form a resist pattern and an etching mask on semiconductor layer 44.

According to the first embodiment, after chip 43 is bonded to substrate 10, mask 46 is formed on chip 43. Wet etching is performed on chip 43 provided with mask 46. Wet etching is unlikely to proceed in the [01−1] direction and the [0−11] direction, but is likely to proceed in the [011] direction and the [0−1−1] direction. Mask 46 includes opening 48. As shown in FIG. 7A, opening 48 has a planar shape of circle and does not include a side perpendicular to the [01−1] direction and the [0−11] direction. In the step of wet etching, a surface having a low etching rate is hardly exposed. The wet etching proceeds in the [100] direction and also in directions parallel to the plane of substrate 40. When the wet etching reaches etching stop layer 42 and reaches four sides of chip 43, substrate 40 is removed. As shown in FIGS. 10A and 10B, the occurrence of residue can be reduced. Semiconductor element 20 can be formed by processing chip 43 having no residue.

Distance D2 from the end portion of opening 48 to side 43d of chip 43 in the [01−1] direction is ¼ to two times the thickness of substrate 40. When the thickness of substrate 40 is 350 μm, distance D2 is in a range of approximately 90 μm to 700 μm, and may be, for example, 100 μm to 500 μm. Distances from the end portion of mask 46 to other sides 43a, 43b and 43c of chip 43 may be approximately equal to distance D2, and may be equal to distance D2.

The wet proceeds in the thickness direction of substrate 40 and also in directions parallel to the plane. When distance D2 is too long, the wet etching does not reach side 43c and side 43d when the wet etching reaches etching stop layer 42. Residues of substrate 40 may remain in the [01−1] direction and the [0−11] direction. When distance D2 is too short, the wet etching reaches side 43c and side 43d before the wet etching proceeds to etching stop layer 42. Substrate 40 remains. Distance D2 from the end portion of mask 46 to the end portion of substrate 40 in the [01−1] direction and the [0−11] direction is set in the range described above. The wet etching proceeds to etching stop layer 42 in the thickness direction and reaches the end portion of chip 43 in the [01−1] direction and the [0−11] direction. Occurrence of residue of substrate 40 can be reduced.

The ratio of the area occupied by opening 48 to the area in the plane of mask 46 (the area inside the dotted line in FIG. 10A) is, for example, about 70%. About 30% of the back surface of substrate 40 is covered with mask 46, and about 70% thereof is exposed from opening 48. The wet etching proceeds from the exposed portion of the back surface of substrate 40 to the portion covered by mask 46. Substrate 40 is removed and the occurrence of residue is reduced. The ratio occupied by opening 48 may be 50% to 90%.

Mask 46 includes one opening 48. Opening 48 has a planar shape of circle. Opening 48 does not include a side perpendicular to the [01−1] direction and the [0−11] direction. A residual part be hardly generated in a wet etching process. Opening 48 may have a planar shape of an ellipse. The short axis of opening 48 is parallel to the [011] direction and the [0−1−1] direction. The long axis is parallel to the [01−1] direction and the [0−11] direction. Opening 48 may have a planar shape of a polygon such as a rhombus. As will be described later, the number of openings may be two or more.

Due to the high etching selectivity between substrate 40 and etching stop layer 42, substrate 40 can be removed by wet etching after bonding. For example, substrate 40 may be formed of InP. Etching stop layer 42 is formed of InGaAs. Hydrochloric acid is used as an etchant for wet etching. Substrate 40 may be removed and wet etching may be stopped at etching stop layer 42. Substrate 40 may include InP or may be formed of a semiconductor other than InP. Etching stop layer 42 may include InGaAs or may be formed of a semiconductor other than InGaAs. The etchant may include a solution other than hydrochloric acid.

Since the generation of residue 40e is reduced, it is possible to form a resist pattern and an etching mask on semiconductor layer 44. Semiconductor layer 44 may be etched to form mesa 30 including a tapered shape as shown in FIG. 1A.

The surface of substrate 40 was assumed to be a (100) plane. The plane orientation of the surface of substrate 40 may be inclined by 15° or less, for example, 2°, 6°, or 15°, with respect to the (100) plane of InP. Even when such substrate 40 is used, the same effect as that of the first embodiment can be obtained. The first direction and the second direction may deviate from the [01−1] direction and the [011] direction within a range of variation in manufacturing. Even when the variation occurs, the same effect can be obtained.

### Second Embodiment

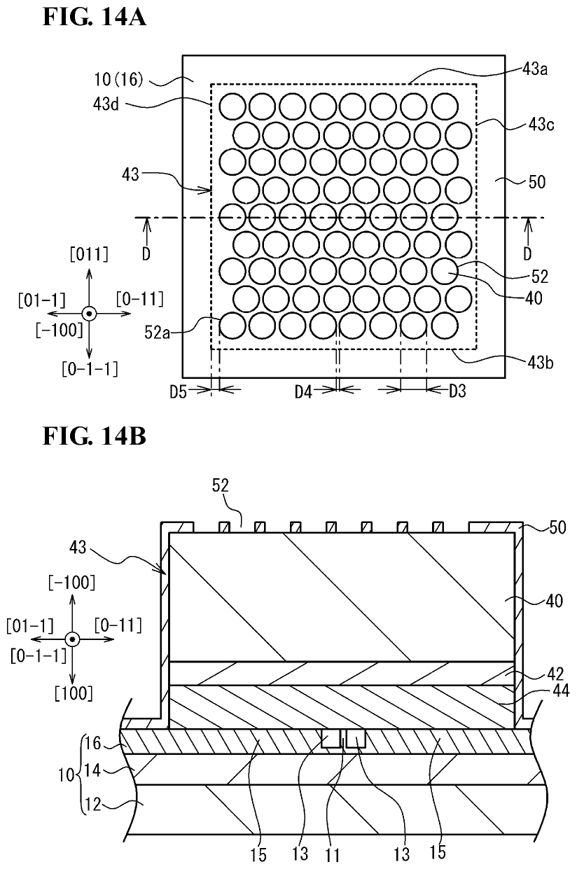

FIG. 14A is a plan view showing a method of fabricating a semiconductor optical element according to a second embodiment. FIG. 14B is a cross-sectional view taken along line D-D of FIG. 14A. FIGS. 14A and 14B show the steps corresponding to FIGS. 8A and 8B of the first embodiment. Description of the same configuration as that of the first embodiment will be omitted.

As shown in FIGS. 14A and 14B, chip 43 is bonded to substrate 10 and a mask 50 is provided with chip 43. Mask 50 is formed of SiO₂ similarly to mask 46, and is used instead of mask 46. Insulating film 45 is provided with chip 43. A resist is provided with Insulating film 45 and resist patterning is performed. A plurality of openings are formed in the resist. The resist pattern is transferred to insulating film 45 to form mask 46.

Mask 50 includes a plurality of openings 52. Substrate 40 is exposed from opening 52. Opening 52 has a planar shape of circle. Eight openings 52 are arranged in the [01−1] direction and the [0−11] direction to form a row. Nine rows of openings 52 are arranged in the [011] direction and the [0−1−1] direction. Diameter D3 of opening 52 is, for example, 10 μm to 100 μm. Distance D4 between two adjacent openings 52 is, for example, 10 μm to 50 μm. Opening 52 closest to the end portion of chip 43 among the plurality of openings 52 is referred to as opening 52a. The shortest distance D5 from the end portion of opening 52a to the end portion of chip 43 is 10 μm to 50 μm, for example.

Substrate 40 is removed by performing wet etching on chip 43 provided with mask 50. Etching stop layer 42 is exposed. The steps after removing substrate 40 are the same as those in the first embodiment.

According to the second embodiment, mask 50 includes a plurality of openings 52. Opening 52 has a shape of circle and does not include a side perpendicular to the [01−1] direction and the [0−11] direction. In the step of wet etching, a surface having a low etching rate is hardly exposed. The wet etching proceeds in the [100] direction and also in directions parallel to the plane of substrate 40. The wet etching also proceeds to portions of substrate 40 under mask 50 and between openings 52. When the wet etching reaches etching stop layer 42 and reaches four sides of chip 43, substrate 40 is removed. The occurrence of residue can be reduced. Semiconductor element 20 can be formed by processing chip 43 having no residue.

Distance D4 between two adjacent openings 52 is two times or less as large as the thickness of substrate 40, for example, 10 μm to 50 μm. A portion of substrate 40 between two openings 52 is removed by wet etching. The occurrence of residue can be suppressed. The shortest distance D5 from the end portion of opening 52a to the end portion of chip 43 is two times or less as large as the thickness of substrate 40, for example, 10 μm to 50 μm. The occurrence of residue can be reduced.

The number and the size of openings 52 may change. The number of openings 52 is larger, one opening 52 is made smaller. As the number is smaller, one opening 52 is made larger. The number of openings 52 may be, for example, four or more, several tens, or 100 or more.

In a second embodiment, the resist is provided with a plurality of circular openings. A plurality of circular openings 52 may be formed in insulating film 45 using a resist. By changing the shape of the opening of the resist, the shape of the opening of the mask can also be changed.

### (First Modification)

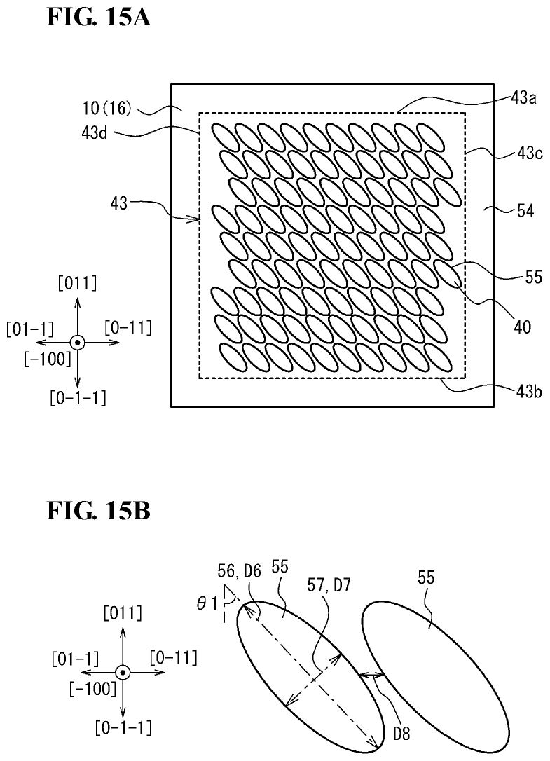

FIG. 15A is a plan view showing a method of fabricating a semiconductor optical element according to a first modification. Description of the same configuration as that of either the first embodiment or the second embodiment will be omitted. As shown in FIG. 15A, chip 43 is provided with a mask 54. Mask 54 includes a plurality of openings 55. Opening 55 has a planar shape of an ellipse.

FIG. 15B is an enlarged view of opening 55, showing two openings 55. As shown in FIG. 15B, opening 55 has a long axis 56 and a short axis 57. Opening 55 is line-symmetric with respect to long axis 56 and line-symmetric with respect to short axis 57. Length D6 of long axis 56 is 10 μm to 100 μm, for example. Length D7 of short axis 57 is 10 μm to 100 μm, for example, and is smaller than length D6 of long axis 56. The shortest distance D8 between two adjacent openings 55 is, for example, 10 μm to 50 μm.

Long axis 56 and short axis 57 are inclined from the [011] direction, the [0−1−1] direction, the [01−1] direction, and the [0−11] direction. Long axis 56 and short axis 57 are not parallel to the (01−1) plane and the (0−11) plane. Each of inclination angle θ1 of long axis 56 from the [011] direction and inclination angle θ1 of long axis 56 from the [0−1−1] direction is, for example, 30° to 150°.

According to the first modification, mask 50 includes a plurality of openings 55. Opening 55 is has a planar shape of an ellipse and does not include a side perpendicular to the [01−1] direction and the [0−11] direction. Long axis 56 and short axis 57 are inclined with respect to the [011] direction and the [0−1−1] direction. In the step of wet etching, a surface having a low etching rate is hardly exposed. The wet etching proceeds in the [100] direction and also in directions parallel to the plane of substrate 40. When the wet etching reaches etching stop layer 42 and reaches four sides of chip 43, substrate 40 is removed. The occurrence of residue can be reduced. Semiconductor element 20 can be formed by processing chip 43 having no residue.

When long axis 56 is parallel to the [011] direction and the [0−1−1] direction, that is, parallel to the (01−1) plane and the (0−11) plane, a plane having a low etching rate is exposed, and a residue is likely to occur. As shown in FIG. 15B, long axis 56 is inclined with respect to the [011] direction and the [0−1−1] direction, and is inclined with respect to the (01−1) plane and the (0−11) plane. A surface having a low etching rate is hardly exposed. Inclination angle θ1 is, for example, 300 to 150°. Long axis 56 deviates from a position parallel to the [011] direction and the [0−1−1] direction. During wet etching, a surface having a low etching rate is hardly be exposed. The occurrence of residue is reduced. Angle θ1 may be, for example, 20° or more, 40° or more, 450 or more, 1400 or less, 1600 or less, or the like.

### (Second Modification)

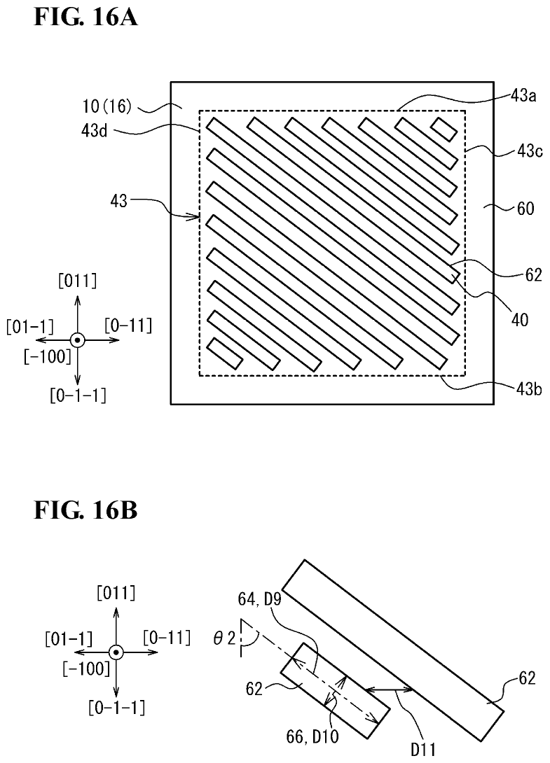

FIG. 16A is a plan view showing a method of fabricating a semiconductor optical element according to a second modification. Description of the same configuration as any one of the first embodiment, the second embodiment, and the first modification will be omitted. As shown in FIG. 16A, chip 43 is provided with a mask 60. Mask 60 includes a plurality of openings 62. Opening 62 has a planar shape of a rectangle. Opening 62 extends between side 43a and side 43c or between side 43b and side 43d of chip 43.

FIG. 16B is an enlarged view of opening 62, showing two openings 62. As shown in FIG. 16B, opening 62 includes a long axis 64 and a short axis 66. Long axis 64 is parallel to the long side of opening 62 and has a length equal to the long side. Short axis 66 is parallel to the short side of opening 62 and has a length equal to the short side. Length D9 of long axis 64 is equal to or longer than length D10 of short axis 66. Length D10 of short axis 66 is, for example, 10 μm to 100 μm. The shortest distance D11 between two adjacent openings 62 is, for example, 10 μm to 50 μm.

Long axis 64 and short axis 66 are inclined from the [011] direction, the [0−1−1] direction, the [01−1] direction, and the [0−11] direction. Long axis 64 and short axis 66 are not parallel to the (01−1) plane and the (0−11) plane. Each of inclination angle θ2 of long axis 64 from the [011] direction and inclination angle θ2 of long axis 64 from the [0−1−1] direction is, for example, 300 to 150°.

According to the second modification, mask 60 includes a plurality of openings 62. Long axis 64 and short axis 66 are inclined with respect to the [011] direction and the [0−1−1] direction. Opening 62 does not include a side perpendicular to the [01−1] direction and the [0−11] direction. In the step of wet etching, a surface having a low etching rate is hardly exposed. It is possible to reduce the occurrence of residues in the wet etching step. Semiconductor element 20 can be formed by processing chip 43 having no residue.

Inclination angle θ2 of long axis 64 is, for example, 30° to 150°. Long axis 64 deviates from a position parallel to the [011] direction and the [0−1−1] direction. During wet etching, a surface having a low etching rate is be hardly exposed. The occurrence of residue is reduced. Angle θ2 may be, for example, 20° or more, 40° or more, 450 or more, 1400 or less, 1600 or less, or the like.

Lengths D10 of short axes 66 of the plurality of openings 62 may be equal to each other. Lengths D10 of the plurality of short axes 66 may include different lengths within a range of, for example, 10 μm to 100 μm. Length D9 of long axis 64 is equal to or longer than length D10 of short axis 66 and shorter than the length of the diagonal line of chip 43. For example, length D9 is determined so that the end portion of opening 62 approaches side 43a and side 43c, or side 43b and side 43d. The shortest distance from the end portion of opening 62 to the end portion of chip 43 is 10 μm to 50 μm, for example.

### (Third Modification)

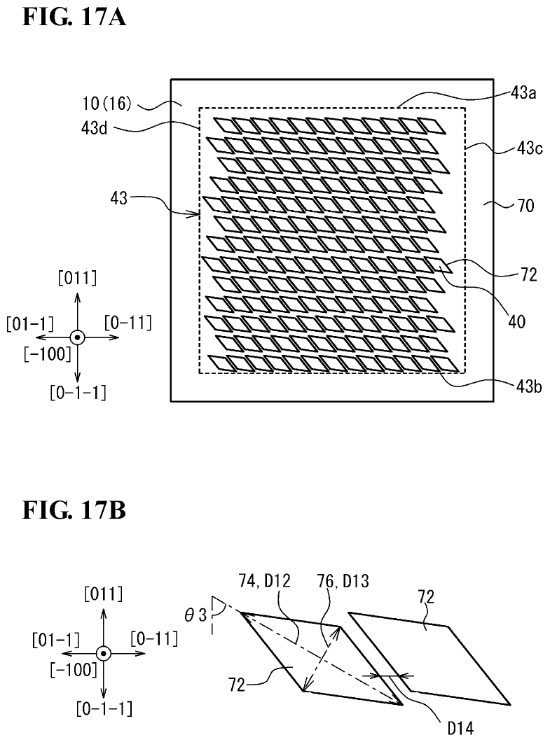

FIG. 17A is a plan view showing a method of manufacturing a semiconductor optical element according to a third modification. Description of the same configuration as any one of the first embodiment, the second embodiment, the first modification, and the second modification will be omitted. As shown in FIG. 17A, chip 43 is provided with a mask 70. Mask 70 includes a plurality of openings 72. Opening 72 has a planar shape of a rhombus.

FIG. 17B is an enlarged view of opening 72, showing two openings 72. As shown in FIG. 17B, opening 72 has a long axis 74 and a short axis 76. Length D12 of long axis 74 is, for example, 10 μm to 100 μm. Length D13 of short axis 76 is 10 μm to 100 μm, for example, and is shorter than length D12 of long axis 74. The shortest distance D14 between two adjacent openings 72 is, for example, 10 μm to 50 μm.

Long axis 74 and short axis 76 are inclined from the [011] direction, the [0−1−1] direction, the [01−1] direction, and the [0−11] direction. Long axis 74 and short axis 76 are not parallel to the (01−1) plane and the (0−11) plane. Each of inclination angle θ3 of long axis 74 from the [011] direction and inclination angle θ3 of long axis 74 from the [0−1−1] direction is, for example, 300 to 150°.

According to the third modification, mask 70 includes a plurality of openings 72. Opening 72 has a planar shape of a rhombus and does not include a side perpendicular to the [01−1] direction and the [0−11] direction. Long axis 74 and short axis 76 are inclined with respect to the [011] direction and the [0−1−1] direction. In the step of wet etching, a surface having a low etching rate is hardly exposed. It is possible to reduce the occurrence of residues in the wet etching step. The semiconductor element 20 can be formed by processing chip 43 having no residue.

Inclination angle θ3 of long axis 74 is, for example, 300 to 150°. Long axis 74 deviates from a position parallel to the [011] direction and the [0−1−1] direction. During wet etching, a surface having a low etching rate is hardly be exposed. The occurrence of residue is reduced. Angle θ3 may be, for example, 200 or more, 400 or more, 450 or more, 1400 or less, 1600 or less, or the like.

As shown in FIG. 14A, the opening may have a planar shape of circle. The opening may have a planar shape including a long axis and a short axis other than a circle. As in the first modification to the third modification, the planar shape of the opening may be a circle, an ellipse, a rectangle, a rhombus, or any other shape.

Although the embodiments of the present disclosure have been described in detail above, the present disclosure is not limited to the specific embodiments, and various modifications and changes can be made within the scope of the gist of the present disclosure described in the claims.

What is claimed is:

1. A method of manufacturing a semiconductor optical element including a chip including a III-V compound semiconductor and a first substrate,
wherein the chip includes a second substrate and a semiconductor layer stacked on the second substrate,
wherein the method comprises:
bonding the semiconductor layer of the chip to the first substrate;
forming a mask on the chip bonded to the first substrate; and
removing the second substrate by performing etching on the chip provided with the mask,
wherein the mask has an opening,
wherein the second substrate is exposed from the opening,
wherein the opening does not have a side perpendicular to a first direction, and wherein the etching in the removing the second substrate is more likely to progress in a second direction intersecting with the first direction than in the first direction.

2. The method of manufacturing a semiconductor optical element according to claim 1, wherein the opening has a planar shape of a circle.

3. The method of manufacturing a semiconductor optical element according to claim 1, wherein the opening of the mask is one opening.

4. The method of manufacturing a semiconductor optical element according to claim 1, wherein a distance from an end portion of the opening to an end portion of the second substrate in the first direction is ¼ to two times a thickness of the second substrate.

5. The method of manufacturing a semiconductor optical element according to claim 1, wherein the opening of the mask includes a plurality of openings.

6. The method of manufacturing a semiconductor optical element according to claim 5, wherein a distance between two of the openings adjacent to each other in the first direction is two times or less as large as a thickness of the second substrate.

7. The method of manufacturing a semiconductor optical element according to claim 5,
wherein the opening has a long axis and a short axis, and
wherein the long axis is inclined with respect to the second direction.

8. The method of manufacturing a semiconductor optical element according to claim 7, wherein the long axis has an inclination angle of 300 to 150° from the second direction.

9. The method of manufacturing a semiconductor optical element according to claim 7, wherein the opening has a planar shape of any one of an ellipse, a rectangle, and a rhombus.

10. The method of manufacturing a semiconductor optical element according to claim 1,
wherein the second substrate includes indium phosphide,
wherein the semiconductor layer includes indium gallium arsenide, and
wherein, in the removing the second substrate, the second substrate is removed by wet etching using an etchant including hydrochloric acid.

11. The method of manufacturing a semiconductor optical element according to claim 1,
wherein the semiconductor layer includes a first semiconductor layer and a second semiconductor layer,
wherein the second substrate, the first semiconductor layer, and the second semiconductor layer are stacked in this order, and
wherein, in the bonding, the second semiconductor layer is bonded to the first substrate, and
wherein the method comprises:
removing the first semiconductor layer after the removing the second substrate; and
etching the second semiconductor layer.
